(19) United States
(12) Patent Application Publication
(10) Pub. No.: US 2024/0282612 A1
(43) Pub. Date: Aug. 22, 2024

(54) ELECTROSTATIC CHUCK AND METHOD OF MANUFACTURING THE SAME

(71) Applicant: TOTO LTD., Fukuoka (JP)

(72) Inventors: Shunya MIYAZAKI, Fukuoka (JP); Jun SHIRAISHI, Fukuoka (JP); Yutaka MOMIYAMA, Fukuoka (JP); Ikuo ITAKURA, Fukuoka (JP)

(73) Assignee: TOTO LTD., Fukuoka (JP)

(21) Appl. No.: 18/443,461

(22) Filed: Feb. 16, 2024

(30) Foreign Application Priority Data
Feb. 22, 2023 (JP) 2023-025987

(51) Int. Cl. H01L 21/683; C23C 16/458; C23C 16/46

(52) U.S. Cl. CPC H01L 21/6833; C23C 16/4586; C23C 16/463

(57) ABSTRACT

An electrostatic chuck 10 includes: a dielectric substrate 100 which includes a surface 110 on which a substrate W is to be placed and in which through holes (gas holes 150 and lift pin holes 160) that penetrate the surface 110 are formed; an electrode terminal 121 which is provided on a surface 120 of the dielectric substrate 100 on an opposite side to the surface 110; a base plate 200 to be joined to the surface 120 of the dielectric substrate 100; and a joining layer 300 which is provided between the dielectric substrate 100 and the base plate 200 and which is formed of an insulating material. When viewed from a direction perpendicular to the surface 110, spaces 340 are formed at positions within the joining layer 300 that do not overlap with any of the through holes and the electrode terminal 121.

### CROSS-REFERENCE TO RELATED APPLICATION

This application is based upon and claims the benefit of priority from Japanese Patent Application No. 2023-025987, filed on Feb. 22, 2023, the entire contents of which are incorporated herein by reference.

### BACKGROUND OF THE INVENTION

### Field of the Invention

The present invention relates to an electrostatic chuck and a method of manufacturing the electrostatic chuck.

### Description of the Related Art

Semiconductor manufacturing equipment such as a CVD device or an etching device is provided with an electrostatic chuck as a device for attracting and holding a substrate such as a silicon wafer to be a processing object. The electrostatic chuck includes a dielectric substrate provided with an attracting electrode and a base plate which supports the dielectric substrate and is configured such that the dielectric substrate and the base plate are joined to each other. While an attracting electrode is generally built into a dielectric substrate, there are cases where a base plate made of metal is used as an attracting electrode. When voltage is applied to the attracting electrode, an electrostatic force is created and a substrate placed on the dielectric substrate is attracted and held.

During processing such as etching, a temperature of the substrate must be maintained at an appropriate temperature. To this end, as described in Japanese Patent Laid-Open No. 2019-165193, it is a practice to supply a gas for cooling between the substrate and the dielectric substrate, pass a refrigerant through a refrigerant flow path of the base plate, and the like.

During processing, in addition to maintaining the temperature of the substrate at an appropriate temperature as described above, it is also required that variability in a temperature distribution (in other words, an in-plane temperature distribution) in each section of the substrate be reduced as much as possible. As a measure to make the in-plane temperature distribution of the substrate nearly uniform, a measure such as providing a plurality of supply paths for a cooling gas and controlling pressure and the like for each path or providing a plurality of refrigerant flow paths and adjusting a refrigerant temperature for each flow path is sometimes taken. However, there may be cases where such a measure by itself cannot sufficiently suppress variability in the in-plane temperature distribution of the substrate.

The present invention has been made in consideration of the problem described above and an object thereof is to provide an electrostatic chuck which is capable of suppressing variability in an in-plane temperature distribution of a substrate.

### SUMMARY OF THE INVENTION

In order to solve the problem described above, an electrostatic chuck according to the present invention includes: a dielectric substrate which includes a placement surface on which an attracted object is to be placed and in which through holes that penetrate the placement surface are formed; an electrode terminal which is provided on a surface of the dielectric substrate on an opposite side to the placement surface; a base plate to be joined to the surface of the dielectric substrate on the opposite side to the placement surface; and a joining layer which is provided between the dielectric substrate and the base plate and which is formed of an insulating material. When viewed from a direction perpendicular to the placement surface, at least one space is formed at a position within the joining layer that does not overlap with any of the through holes and the electrode terminal.

In the electrostatic chuck configured as described above, the at least one space in the joining layer can be made to function as a “heat insulating layer”. For example, by arranging the at least one space in the joining layer at a position within the substrate directly below a portion at which a temperature tends to be low, temperatures of the dielectric substrate and the substrate directly above this position can be raised and the in-plane temperature distribution of the substrate can be made nearly uniform.

In addition, also preferably, in the electrostatic chuck according to the present invention, in a case of viewing from a direction perpendicular to the placement surface, when a proportion occupied by an area of the at least one space per unit area of the joining layer is assumed to be a space proportion, the space proportion in a central part of the joining layer is larger than the space proportion in an outer circumferential part of the joining layer. Increasing the space proportion in the central part enables a temperature of the central part of the substrate which tends to be low to be raised and enables the in-plane temperature distribution of the substrate to be made nearly uniform.

Furthermore, also preferably, in the electrostatic chuck according to the present invention, the at least one space comprises spaces formed in plurality, and a density of the spaces in a central part of the joining layer is higher than a density of the spaces in an outer circumferential part of the joining layer. Increasing the space proportion in the central part by increasing the density of the spaces enables the in-plane temperature distribution of the substrate to be made nearly uniform. Note that a “density of the spaces” refers to the number of spaces arranged per unit area.

Furthermore, also preferably, in the electrostatic chuck according to the present invention, the at least one space comprises spaces formed in plurality, and each of the spaces arranged in a central part of the joining layer is larger than each of the spaces arranged in an outer circumferential part of the joining layer. Increasing the space proportion in the central part by adjusting the size of each of the spaces enables the in-plane temperature distribution of the substrate to be made nearly uniform.

In addition, preferably, in the electrostatic chuck according to the present invention, the at least one space is formed so as to penetrate the joining layer in a direction perpendicular to the placement surface. Securing a maximum thickness of the at least one space which functions as a heat insulating layer enables an effect of temperature regulation with respect to the substrate to be enhanced.

Furthermore, in the electrostatic chuck according to the present invention, an insulator film is also preferably provided on a surface of the base plate on the joining layer-side. In such a configuration, since the surface of the base plate becomes covered by both the joining layer and the insulator film, an occurrence of a discharge between the substrate and the base plate can be suppressed.

In addition, in the electrostatic chuck according to the present invention, the insulator film is also preferably a film formed by spraying. In such a configuration, a film with high insulation properties can be readily formed and the occurrence of a discharge can be suppressed.

Furthermore, in the electrostatic chuck according to the present invention, the joining layer is also preferably a layer created by curing a solid adhesive sheet on which a space part which is a depression or a through hole is formed in advance. In such a configuration, in a state prior to joining, the depression or the through hole to be at least one space can be readily formed with respect to the adhesive sheet. In addition, the at least one space can be reliably prevented from deforming or disappearing in the step of curing the adhesive.

In addition, also preferably, in the electrostatic chuck according to the present invention, a refrigerant flow path for passing a refrigerant is formed in the base plate, and in a case of viewing from a direction perpendicular to the placement surface, when a proportion occupied by an area of the at least one space per unit area of the joining layer is assumed to be a space proportion, the space proportion in a first portion of the joining layer which overlaps with an upstream side of the refrigerant flow path is larger than the space proportion in a second portion of the joining layer which overlaps with a downstream side of the refrigerant flow path.

In semiconductor manufacturing equipment, cleaning inside the equipment may be successively performed after the processing of the substrate is completed. While the base plate is supplied with a low-temperature refrigerant during processing of the substrate, once cleaning starts, the base plate is supplied with a refrigerant at a higher temperature than before. Therefore, immediately after the start of cleaning, the temperature of the base plate on the upstream side of the refrigerant flow path rises first and the temperature of the base plate on the downstream side of the refrigerant flow path rises later. In this manner, a temporary temperature difference is created in the base plate upon the start of cleaning. Although a similar temperature difference is also created in the dielectric substrate due to heat transfer from the base plate, since a ceramic sintered compact is often used as the dielectric substrate, such a temperature difference is not preferable.

As a countermeasure, in the electrostatic chuck configured as described above, the space proportion in the first portion of the joining layer which overlaps with an upstream side of the refrigerant flow path is made larger than the space proportion in a second portion of the joining layer which overlaps with a downstream side of the refrigerant flow path. While heat transfer from a portion of the base plate that reaches a high temperature first to the dielectric substrate is suppressed by the first portion, heat transfer from a portion that reaches a high temperature later to the dielectric substrate is relatively promoted by the second portion. Accordingly, a temperature difference in the dielectric substrate can be suppressed.

In addition, also preferably, in the electrostatic chuck according to the present invention, when viewed from a direction perpendicular to the placement surface, the first portion is at a position closer to center than the second portion.

During the processing of the substrate, a temperature of the central part of the substrate tends to be lower than that of an outer circumferential part of the substrate. In the electrostatic chuck configured as described above, by providing the first portion of which the space proportion is high at a position closer to the center, the temperature of the central part of the substrate can be raised during processing and the in-plane temperature distribution can be made nearly uniform.

A method of manufacturing an electrostatic chuck according to the present invention includes the steps of: preparing a dielectric substrate which includes a placement surface on which an attracted object is to be placed, in which through holes that penetrate the placement surface are formed, and in which an electrode terminal is provided on a surface on an opposite side to the placement surface; preparing a base plate; preparing a solid adhesive sheet which is an insulating member and on which a space part being a depression or a through hole has been formed; causing a surface of the dielectric substrate on the opposite side to the placement surface and the base plate to oppose each other and sandwiching the adhesive sheet between the dielectric substrate and the base plate so that the space part does not overlap with both the through holes and the electrode terminal; and curing the adhesive sheet.

According to such a method of manufacturing an electrostatic chuck, an electrostatic chuck capable of suppressing variability of an in-plane temperature distribution of a substrate as described above can be readily manufactured.

### Advantageous Effect of Invention

According to the present invention, an electrostatic chuck which is capable of suppressing variability in an in-plane temperature distribution of a substrate can be provided.

### BRIEF DESCRIPTION OF THE DRAWINGS

FIG. 1 is a sectional view schematically showing a configuration of an electrostatic chuck according to a first embodiment;

FIG. 2 is a diagram showing a configuration of a joining layer included in the electrostatic chuck shown in FIG. 1;

FIG. 3 is a diagram showing a configuration of the joining layer included in the electrostatic chuck shown in FIG. 1;

FIG. 4A is a diagram for describing a configuration of a joining layer according to a modification;

FIG. 4B is a diagram for describing a configuration of a joining layer according to a modification;

FIG. 5 is a diagram for describing a method of manufacturing the electrostatic chuck shown in FIG. 1;

FIG. 6 is a diagram showing a configuration of a joining layer included in an electrostatic chuck according to a second embodiment;

FIG. 7 is a diagram showing a configuration of a joining layer included in an electrostatic chuck according to a third embodiment;

FIG. 8 is a diagram showing a configuration of a joining layer included in an electrostatic chuck according to a fourth embodiment;

FIG. 9A is a diagram showing a configuration of a joining layer and the like included in an electrostatic chuck according to a fifth embodiment; and

FIG. 9B is a diagram showing a configuration of the joining layer and the like included in the electrostatic chuck according to the fifth embodiment.

### DETAILED DESCRIPTION OF THE PREFERRED EMBODIMENTS

Hereinafter, embodiments of the present invention will be described with reference to the accompanying drawings. In order to facilitate understanding of the description, same constituent elements in the respective drawings will be denoted by same reference signs whenever possible and redundant descriptions will not be repeated.

A first embodiment will be described. An electrostatic chuck 10 according to the present embodiment attracts a substrate W to be a processing object using an electrostatic force and holds the substrate W inside semiconductor manufacturing equipment (not illustrated) such as a CVD film deposition device. For example, the substrate W is a silicon wafer. The electrostatic chuck 10 may be used in devices other than semiconductor manufacturing equipment.

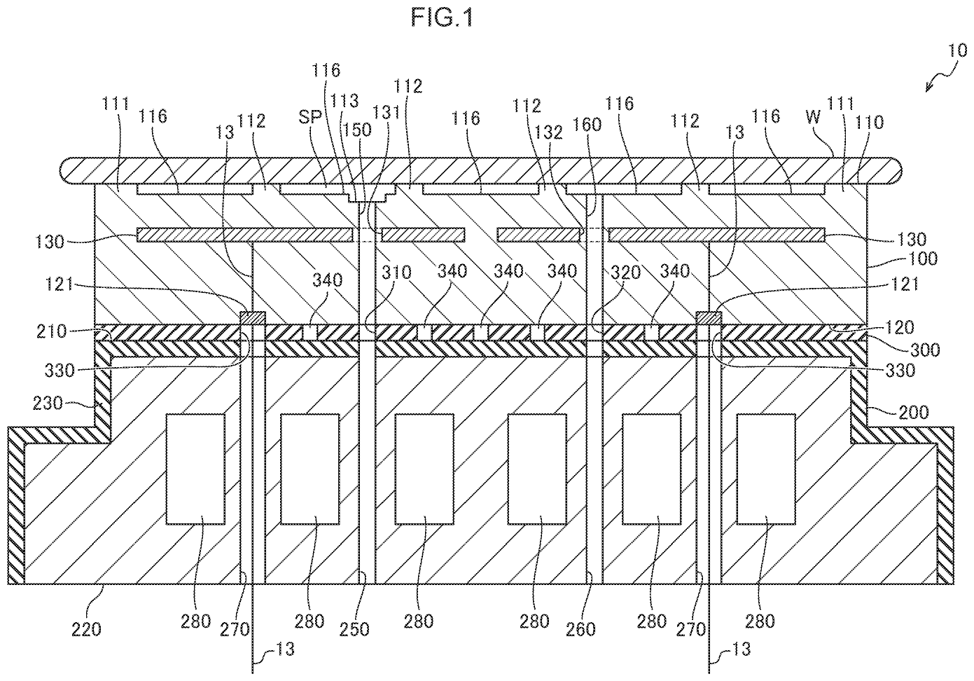

FIG. 1 shows a configuration of the electrostatic chuck 10 in a state where the substrate W has been attracted and is held as a schematic sectional view. The electrostatic chuck 10 includes a dielectric substrate 100, a base plate 200, and a joining layer 300.

The dielectric substrate 100 is an approximately disk-shaped member made of a ceramic sintered compact. While the dielectric substrate 100 includes, for example, high-grade aluminum oxide (Al₂O₃), the dielectric substrate 100 may include other materials. A purity, a type, an additive, and the like of ceramics in the dielectric substrate 100 can be appropriately set in consideration of plasma resistance and the like which are required of the dielectric substrate 100 in the semiconductor manufacturing equipment.

An upper-side surface 110 in FIG. 1 of the dielectric substrate 100 is a “placement surface” on which the substrate W that is an attracted object is to be placed. In addition, a lower-side surface 120 in FIG. 1 of the dielectric substrate 100 is a “joined surface” to be joined to the base plate 200 via the joining layer 300 to be described later. Hereinafter, a point of view when viewing the electrostatic chuck 10 from a side of the surface 110 in a direction perpendicular to the surface 110 will also be notated as a “top view”.

An attracting electrode 130 is embedded in the dielectric substrate 100. The attracting electrode 130 is a thin plate-like layer formed of a metal material such as tungsten and is arranged so as to be parallel to the surface 110. When voltage is applied to the attracting electrode 130 from outside via a power feed path 13, an electrostatic force is created between the surface 110 and the substrate W and, accordingly, the substrate W is attracted and held. While two attracting electrodes 130 may be provided as so-called “bipolar” electrodes as in the present embodiment, alternatively, only one attracting electrode 130 may be provided as a so-called “monopolar” electrode.

In FIG. 1, an entirety of the power feed path 13 is drawn in a simplified manner. Within the power feed path 13, a portion inside the dielectric substrate 100 is configured as, for example, an elongated via (hole) filled with a conductive material and an electrode terminal 121 is provided at a lower end thereof. The electrode terminal 121 is embedded via an insulation member (not illustrated) on the surface 120 on an opposite side to the surface 110. A portion of the power feed path 13 which penetrates the base plate 200 is a rod-like metal (busbar) of which one end is connected to the electrode terminal 121. A through hole 270 for inserting the metal is formed in the base plate 200.

A space SP is formed between the dielectric substrate 100 and the substrate W. When processing such as film deposition is performed in the semiconductor manufacturing equipment, helium gas for temperature regulation is supplied to the space SP from outside via a gas hole 150 to be described later. By interposing the helium gas between the dielectric substrate 100 and the substrate W, thermal resistance between the dielectric substrate 100 and the substrate W is regulated and, accordingly, the substrate W is kept at an appropriate temperature. Note that the gas for temperature regulation which is supplied to the space SP may be a gas other than helium.

A seal ring 111 and a dot 112 are provided on the surface 110 being an attraction surface and the space SP is formed around the seal ring 111 and the dot 112.

The seal ring 111 is a wall that partitions the space SP at an outermost position. An upper end of each seal ring 111 constitutes a part of the surface 110 and abuts the substrate W. Note that a plurality of seal rings 111 may be provided so as to divide the space SP. Adopting such a configuration enables pressure of helium gas in each divided space SP to be individually regulated and enables a surface temperature distribution of the substrate W during processing to be made nearly uniform.

In FIG. 1 and the like, portions denoted by a reference sign “116” are a bottom surface of the space SP. Hereinafter, the portions will also be referred to as the “bottom surface 116”. The seal rings 111 are formed together with the dot 112 to be described next as a result of thinning parts of the surface 110 down to a position of the bottom surface 116.

The dot 112 is a circular projection that protrudes from the bottom surface 116. The dot 112 is provided in plurality and arranged so as to be approximately uniformly distributed over the attraction surface of the dielectric substrate 100. An upper end of each dot 112 constitutes a part of the surface 110 and abuts the substrate W. Providing the dot 112 described above in plurality suppresses deflection of the substrate W.

A groove 113 is formed on the bottom surface 116 of each space SP. The groove 113 is a groove formed to cause the bottom surface 116 to further retreat towards the side of the surface 120. The groove 113 is formed in order to quickly diffuse the helium gas supplied from the gas hole 150 into the space SP and to make a pressure distribution in the space SP approximately uniform in a short period of time.

The gas hole 150 is formed in the dielectric substrate 100 so as to perpendicularly penetrate the dielectric substrate 100 from the surface 110 toward the surface 120. While the gas hole 150 is formed in plurality, only one gas hole 150 is shown in FIG. 1. An end of the gas hole 150 on the side of the space SP opens on the bottom surface of the groove 113. The gas hole 150 corresponds to a “through hole” formed so as to penetrate the surface 110 of the dielectric substrate 100. In portions of the attracting electrode 130 which intersects with each gas hole 150, an opening 131 for avoiding interference with the gas hole 150 is formed. Due to forming the opening 131, since the attracting electrode 130 is not exposed on an inner surface of the gas hole 150, discharge between the substrate W and the attracting electrode 130 is prevented.

A lift pin hole 160 is further formed in the dielectric substrate 100 so as to perpendicularly penetrate the dielectric substrate 100 from the surface 110 toward the side of the surface 120. The lift pin hole 160 is a hole into which a lift pin (not illustrated) provided in the semiconductor manufacturing equipment is to be inserted. While a total of three lift pin holes 160 are formed and arranged so as to be equally spaced at 120-degree intervals, only one of the three lift pin holes 160 is illustrated in FIG. 1. Due to the lift pins that move up and down through the lift pin holes 160, the substrate W is attached to and detached from the surface 110 of the dielectric substrate 100. The lift pin holes 160 correspond to a “through hole” formed so as to penetrate the surface 110 of the dielectric substrate 100 in a similar manner to the gas holes 150 described above. In portions of the attracting electrode 130 which intersects with each lift pin hole 160, an opening 132 for avoiding interference with the lift pin hole 160 is formed. Due to forming the opening 132, since the attracting electrode 130 is not exposed on an inner surface of the lift pin hole 160, discharge between the substrate W and the attracting electrode 130 is prevented.

The base plate 200 is an approximately disk-shaped member which is joined to the surface 120 of the dielectric substrate 100 in order to support the dielectric substrate 100. For example, the base plate 200 is formed of a metal such as aluminum. An upper-side surface 210 in FIG. 1 of the base plate 200 is a “joined surface” to be joined to the dielectric substrate 100 via the joining layer 300.

An insulator film 230 is formed on approximately the entire surface of the base plate 200 excluding a lower-side surface 220 in FIG. 1. The insulator film 230 is, for example, a film made of an insulating material such as alumina and is formed by, for example, spraying. An entirety of the surface 210 described earlier constitutes a surface on the insulator film 230.

In such a configuration, since the surface of the base plate 200 becomes covered by both the joining layer 300 to be described later and the insulator film 230, an occurrence of a discharge between the substrate W and the base plate 200 can be suppressed. While the insulator film 230 is preferably an alumina film formed by spraying as in the present embodiment, the insulator film 230 may be a film formed by other methods or a film made of other materials.

Note that a range where the insulator film 230 is formed on the base plate 200 may differ from a range according to the example shown in FIG. 1. For example, the insulator film 230 may only be formed in a range of the surface 210 which is a joined surface. When discharge can be sufficiently prevented by only the joining layer 300, the insulator film 230 need not be provided.

A refrigerant flow path 280 for supplying a refrigerant is formed inside the base plate 200. When processing such as film deposition is performed in the semiconductor manufacturing equipment, the refrigerant is supplied to the refrigerant flow path 280 from the outside and the base plate 200 is cooled by the refrigerant. Heat generated on the substrate W during the processing is transferred to the refrigerant via the helium gas in the space SP, the dielectric substrate 100, and the base plate 200 and discharged to the outside together with the refrigerant.

A gas hole 250 which perpendicularly extends from the surface 210 toward the side of the surface 220 is formed in the base plate 200. The gas hole 250 is formed at each position overlapping with the gas hole 150 of the dielectric substrate 100 in a top view and is communicated with the gas hole 150 via a through hole 310 provided in the joining layer 300. Together with the gas hole 150 of the dielectric substrate 100, the gas hole 250 constitutes a part of a path for supplying helium gas towards the space SP.

While the gas hole 250 may be formed so that the entire gas hole 250 extends linearly as in the present embodiment, alternatively, the gas hole 250 may be formed so as to bend before reaching the surface 220. In addition, a configuration may be adopted in which after consolidating a plurality of the gas holes 250 on the side of the surface 210 into a small number of flow paths inside the base plate 200, the flow paths are extended to the side of the surface 220.

A lift pin hole 260 is further formed in the base plate 200 so as to perpendicularly penetrate the base plate 200 from the surface 210 toward the side of the surface 220. The lift pin hole 260 is a hole into which a lift pin (not illustrated) provided in the semiconductor manufacturing equipment is to be inserted in a similar manner to the lift pin hole 160 of the dielectric substrate 100. The lift pin hole 260 is formed at each position overlapping with the lift pin hole 160 of the dielectric substrate 100 in a top view and is communicated with the lift pin hole 160 via a through hole 320 provided in the joining layer 300.

The joining layer 300 is a layer provided between the dielectric substrate 100 and the base plate 200 to join the dielectric substrate 100 and the base plate 200 to each other. The joining layer 300 is created by curing an adhesive made of an insulating material. As such an adhesive, for example, a polyimide-based adhesive can be used.

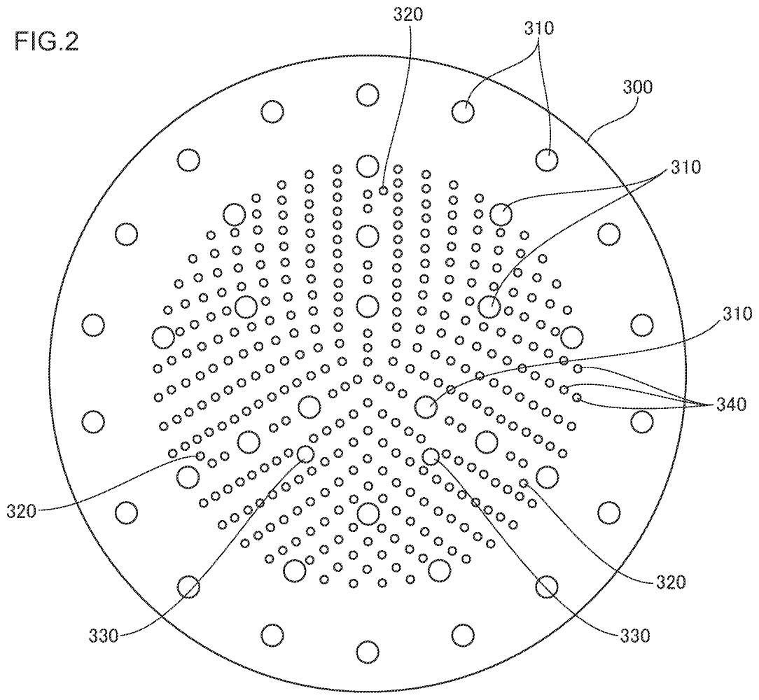

FIG. 2 is a diagram in which the joining layer 300 is drawn in a top view. As shown in FIG. 2, a plurality of through holes are formed in the joining layer 300. The through holes include through holes 310, 320, 330, and 340.

As described earlier, the through hole 310 is a hole that is formed in order to communicate the gas hole 150 and the gas hole 250 with each other. As described earlier, the through hole 320 is a hole that is formed in order to communicate the lift pin hole 160 and the lift pin hole 260 with each other.

The through hole 330 is formed at each position overlapping with the electrode terminal 121 and the through hole 270 in a top view. As shown in FIG. 1, the through hole 330 is a hole for passing the power feed path 13.

In addition to the attracting electrode 130, another electrode such as an RF electrode may be embedded in the dielectric substrate 100. In this case, an electrode terminal to be connected to the electrode is provided on the surface 120 of the dielectric substrate 100. In addition, a further through hole for passing a power feed path to be connected to the electrode terminal is formed at each of positions within the joining layer 300 which overlaps with the electrode terminal.

Each of the through holes 340 is a hole formed at a position which does not overlap with any of the through holes 310, 320, and 330 and the electrode terminal 121 described above. In other words, each of the through holes 340 is a hole formed at a position which does not overlap with any of the through holes (the gas holes 150 and the lift pin holes 160) formed in the dielectric substrate 100 and the electrode terminal 121 in a top view. A space formed inside each through hole 340 functions as a “heat insulating layer” that prevents heat transfer between the dielectric substrate 100 and the base plate 200. Hereinafter, the space formed inside each through hole 340 will also be notated as a “space 340”.

In the electrostatic chuck 10 according to the present embodiment, the space 340 which is a heat insulating layer is arranged in plurality in the joining layer 300 so that the in-plane temperature distribution of the substrate W during processing becomes uniform. For example, by arranging the space 340 in the joining layer 300 at a position within the substrate W to be directly under a portion at which a temperature tends to be low, since cooling due to the base plate 200 is suppressed directly above the position, the temperatures of the dielectric substrate 100 and the substrate W locally rise. Accordingly, the in-plane temperature distribution of the substrate W can be made nearly uniform.

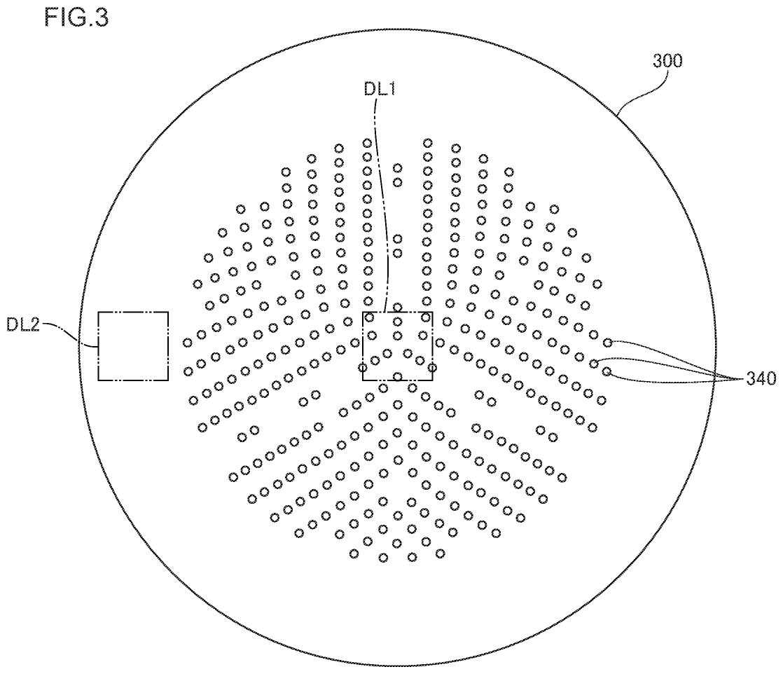

A specific arrangement of the spaces 340 will be described. To make the arrangement of the spaces 340 clearer, in FIG. 3, illustration of the through holes 310, 320, and 330 is omitted and only the spaces 340 are illustrated as compared to FIG. 2.

In the present embodiment, the spaces 340 are formed in plurality in the joining layer 300 and all of the spaces 340 are circular spaces in a top view. In addition, the shapes of the respective spaces 340 are all the same.

Now, a proportion occupied by an area of the spaces 340 per unit area of the joining layer 300 will be defined as a “space proportion” when viewing from a direction perpendicular to the surface 110 which is a placement surface. While a size of the “unit area” is not particularly limited, an area more or less capable of including a plurality of a largest space 340 such as a region enclosed by a dotted line DL1 in FIG. 3 may be set as the “unit area” described above.

As shown in FIG. 3, in the present embodiment, the spaces 340 are not evenly arranged over the entire joining layer 300. Specifically, the plurality of spaces 340 are arranged so that the space proportion in a central part of the joining layer 300 becomes larger than the space proportion in an outer circumferential part of the joining layer 300. The “central part of the joining layer 300” refers to, for example, the region enclosed by the dotted line DL1 in FIG. 3 and the “outer circumferential part of the joining layer 300” refers to, for example, a region enclosed by a dotted line DL2 in FIG. 3. Sizes of the regions respectively enclosed by the dotted lines DL1 and DL2 are the same. The space proportion can also be described as, in a region enclosed by each dotted line, a proportion occupied by a total area of the spaces 340 included in the region.

In order to evenly perform processing such as film formation or etching over the entire substrate W, the in-plane temperature distribution of the substrate W is desirably made as uniform as possible during the processing. However, the outer circumferential part of the substrate W is less readily cooled by the electrostatic chuck 10 as compared to the central part of the substrate W and the temperature of the outer circumferential part tends to be higher than that of the central part. In other words, during processing of the substrate W, the temperature of the central part of the substrate W tends to be lower than that of the outer circumferential part of the substrate W.

In consideration thereof, in the electrostatic chuck 10 according to the present embodiment, the space proportion in the central part of the joining layer 300 is made larger than the space proportion in the outer circumferential part of the joining layer 300. Since the central part of the substrate W at which the temperature tends to become low is less readily cooled by the base plate 200 due to the arrangement of the spaces 340, the temperature of the central part rises to approach the temperature of the outer circumferential part. Accordingly, the in-plane temperature distribution of the substrate W can be made nearly uniform.

In the present embodiment, by making the respective shapes of the spaces 340 formed in plurality the same, the respective spaces 340 are arranged so that a density of the spaces 340 in the central part of the joining layer 300 becomes higher than a density of the spaces 340 in the outer circumferential part of the joining layer 300. Increasing the space proportion in the central part of the joining layer 300 by increasing the density of the spaces 340 enables the in-plane temperature distribution of the substrate W to be made nearly uniform. Note that a “density of the spaces 340” refers to the number of the spaces 340 arranged per unit area.

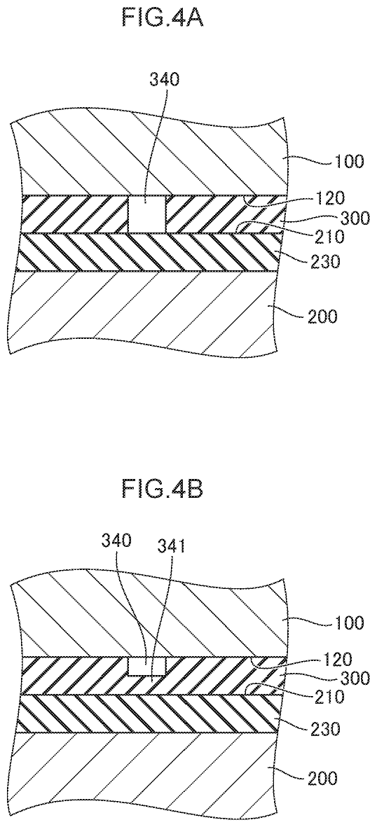

As shown in FIGS. 1 and 4A, each space 340 is formed as a “through hole” which penetrates the joining layer 300 in a direction perpendicular to the surface 110 which is a placement surface. As an alternative to such an aspect, each space 340 may be formed as an internal space of a “bottomed hole” which has a bottom part 341 on the side of the base plate 200 as in a modification shown in FIG. 4B. In other words, each space 340 may be formed as an internal space of a “depression” instead of as a “through hole”. However, from the perspective of securing a maximum thickness of the spaces 340 which function as a heat insulating layer and further enhancing an effect of temperature regulation with respect to the substrate W, the spaces 340 are preferably formed as internal spaces of through holes as in the present embodiment.

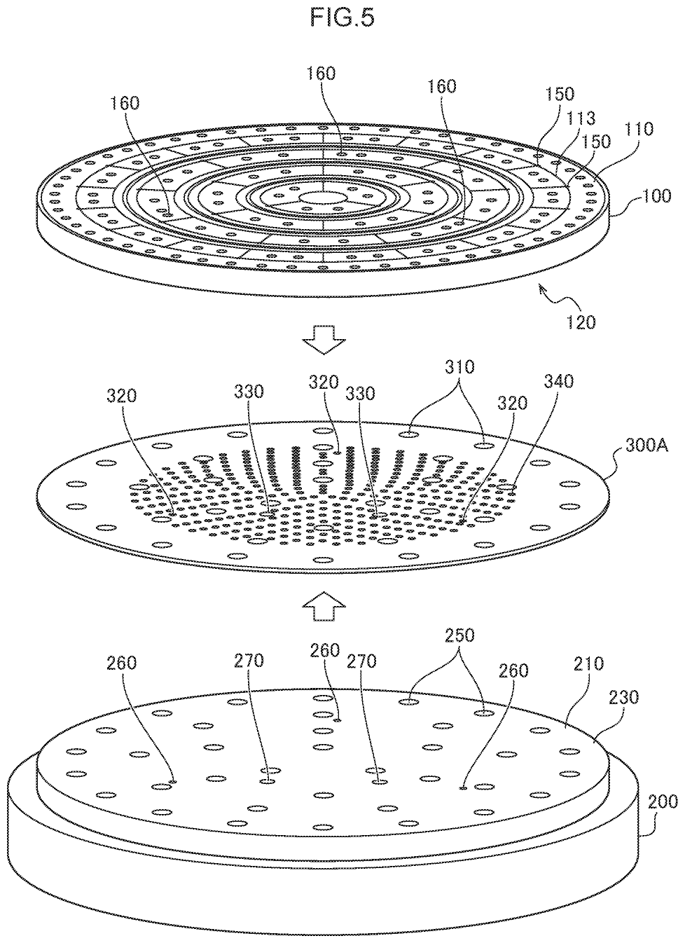

A method of manufacturing the electrostatic chuck 10 will be briefly described. First, as shown in FIG. 5, the dielectric substrate 100, the base plate 200, and an adhesive sheet 300A are respectively prepared. Subsequently, the dielectric substrate 100 and the base plate 200 are joined to each other using the adhesive sheet 300A.

The dielectric substrate 100 is in a state where the gas holes 150 and the lift pin holes 160 which penetrate the surface 110, the attracting electrodes 130, the electrode terminal 121, and the like have been formed in advance prior to joining. As methods of forming these elements, various known methods can be adopted.

In a similar manner, the base plate 200 is also in a state where the gas holes 250 and the lift pin holes 260, the refrigerant flow paths 280, the insulator film 230, and the like have been formed in advance prior to joining. As methods of forming these elements, various known methods can be adopted.

The adhesive sheet 300A is an insulating member to become the joining layer 300 by being cured upon joining. In other words, while the adhesive sheet 300A is an “adhesive”, the adhesive sheet 300A does not assume a liquid form even in a stage prior to curing and is a solid sheet-like member with flexibility. As the adhesive sheet 300A, for example, an adhesive film which is polyimide-based, epoxy-based, silicone-based, or acrylic-based can be used. As the adhesive film, a film with superior thermal conductivity or high insulation properties can be suitably used.

Since the adhesive sheet 300A has a solid sheet shape even prior to curing as described above, for example, by applying punching using a die or the like, the through holes 310, 320, 330, and 340 and the like can be formed in advance prior to joining. The through holes 340 are holes formed in the adhesive sheet 300A in advance so as to finally become the spaces 340 and correspond to the “space part” according to the present embodiment.

After preparing the dielectric substrate 100, the base plate 200, and the adhesive sheet 300A provided with the through holes 340 and the like as described above, as shown in FIG. 5, the adhesive sheet 300A is sandwiched between the dielectric substrate 100 and the base plate 200. Specifically, the surface 120 of the dielectric substrate 100 and the surface 210 of the base plate 200 are caused to oppose each other and the adhesive sheet 300A is sandwiched between the dielectric substrate 100 and the base plate 200 so that the through holes 340 do not overlap with any of the gas holes 150, the lift pin holes 160, and the electrode terminal 121.

In a state where the adhesive sheet 300A is sandwiched as described above, entireties of the dielectric substrate 100, the base plate 200, and the adhesive sheet 300A are heated up to a predetermined temperature. Due to the heating, the adhesive sheet 300A is cured in a state of being joined to both the surface 120 and the surface 210 and becomes the joining layer 300 shown in FIG. 1. The through holes 340 and the like having been formed in advance in the adhesive sheet 300A more or less retain their original shapes even after the adhesive sheet 300A is cured. According to the method described above, the electrostatic chuck 10 configured as shown in FIG. 1 is completed.

As described above, the joining layer 300 according to the present embodiment is created by curing the solid adhesive sheet 300A in which the through holes 340 have been formed in advance. Using the adhesive sheet 300A enables the through holes 340 with a predetermined shape to be readily formed in a stage prior to joining in a portion (the adhesive sheet 300A) to become the joining layer 300. In addition, the spaces 340 can be reliably prevented from deforming or disappearing in the step of curing the adhesive.

If the deformation of the spaces 340 and the like during curing can be prevented in some way, a liquid adhesive can be used instead of the adhesive sheet 300A as the adhesive to become the joining layer 300. For example, by performing bonding after arranging, in advance, a string-like solid member to act as a “levee” for preventing penetration by a liquid adhesive along an outer periphery of regions to become the spaces 340 and the like, the joining layer 300 similar to that of the present embodiment can be formed.

When each of the spaces 340 is to be formed as an internal space of a “bottomed hole” which has the bottom part 341 on the side of the base plate 200 as in the modification shown in FIG. 4B, a bottomed hole (in other words, a depression) may be formed instead of a through hole in advance at corresponding positions of the adhesive sheet 300A. In this case, the depressions formed on the adhesive sheet 300A are to correspond to “space parts” which finally become the spaces 340.

A second embodiment will be described. Hereinafter, differences from the first embodiment will be mainly described and descriptions of features in common with the first embodiment will be omitted when appropriate.

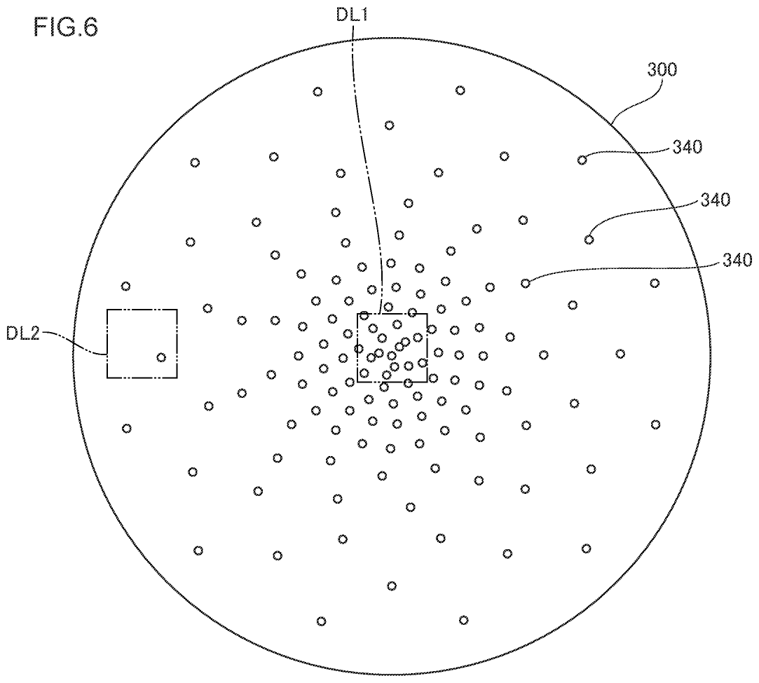

The present embodiment differs from the first embodiment in the arrangement of the spaces 340 formed in the joining layer 300. In FIG. 6, a configuration of the joining layer 300 according to the present embodiment is schematically drawn using a similar method to FIG. 3.

In the present embodiment, the spaces 340 are formed in plurality in the joining layer 300 and all of the spaces 340 are circular spaces in a top view in a similar manner to the first embodiment. In addition, the shapes of the respective spaces 340 are all the same.

As shown in FIG. 6, in the present embodiment, each space 340 is arranged so that the density of the spaces 340 gradually becomes (instead of in stages) sparse from the center to the outer circumferential side of the joining layer 300. Therefore, the “space proportion” described earlier gradually decreases from the center toward the outer circumferential side of the joining layer 300. Even with such an aspect, since the space proportion in the central part (for example, a region enclosed by the dotted line DL1) of the joining layer 300 becomes larger than the space proportion in the outer circumferential part (for example, a region enclosed by the dotted line DL2) of the joining layer 300, a similar effect to that described in the first embodiment is produced.

A third embodiment will be described. Hereinafter, differences from the first embodiment will be mainly described and descriptions of features in common with the first embodiment will be omitted when appropriate.

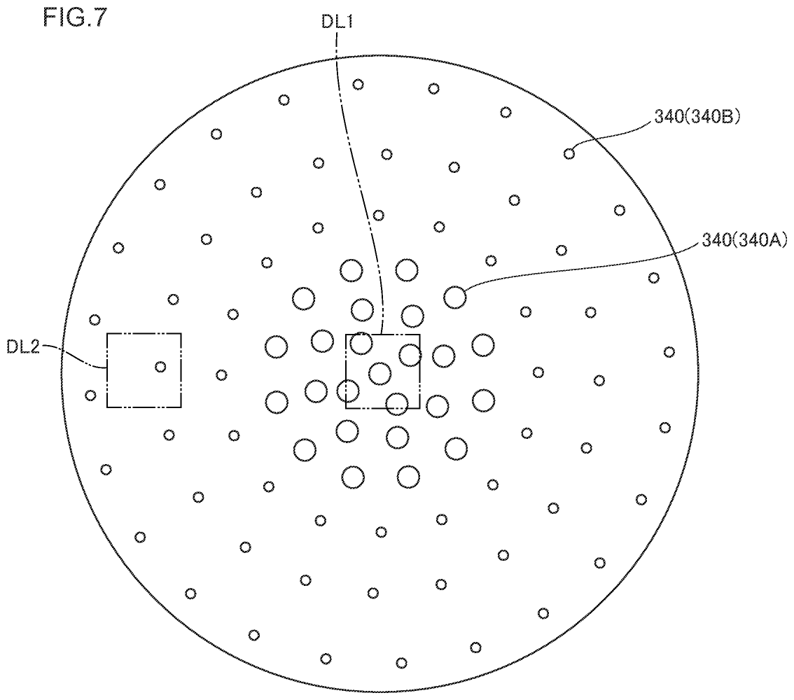

The present embodiment also differs from the first embodiment in the arrangement of the spaces 340 formed in the joining layer 300. In FIG. 7, a configuration of the joining layer 300 according to the present embodiment is schematically drawn using a similar method to FIG. 3.

In the present embodiment, the spaces 340 are formed in plurality in the joining layer 300 and all of the spaces 340 are circular spaces in a top view in a similar manner to the first embodiment. However, the shapes of the respective spaces 340 are not all the same. The spaces 340 according to the present embodiment include spaces 340A of which a diameter is relatively large and spaces 340B of which a diameter is relatively small.

The spaces 340A are arranged in a region close to the center of the joining layer 300 and the spaces 340B are arranged in a region outside of this region. In other words, each of the spaces 340A arranged in a central part of the joining layer 300 is larger than each of the spaces 340B arranged in an outer circumferential part of the joining layer 300. As a result, the space proportion in the central part (for example, a region enclosed by the dotted line DL1) of the joining layer 300 becomes larger than the space proportion in the outer circumferential part (for example, a region enclosed by the dotted line DL2) of the joining layer 300. In this manner, a similar effect to that described in the first embodiment can be produced even with a configuration in which the space proportion of the central part is increased by adjusting the size of each of the spaces 340.

Note that an aspect in which the spaces 340 gradually (instead of in stages) become larger from the center toward the outer circumferential side of the joining layer 300 may also be adopted.

A fourth embodiment will be described. Hereinafter, differences from the first embodiment will be mainly described and descriptions of features in common with the first embodiment will be omitted when appropriate.

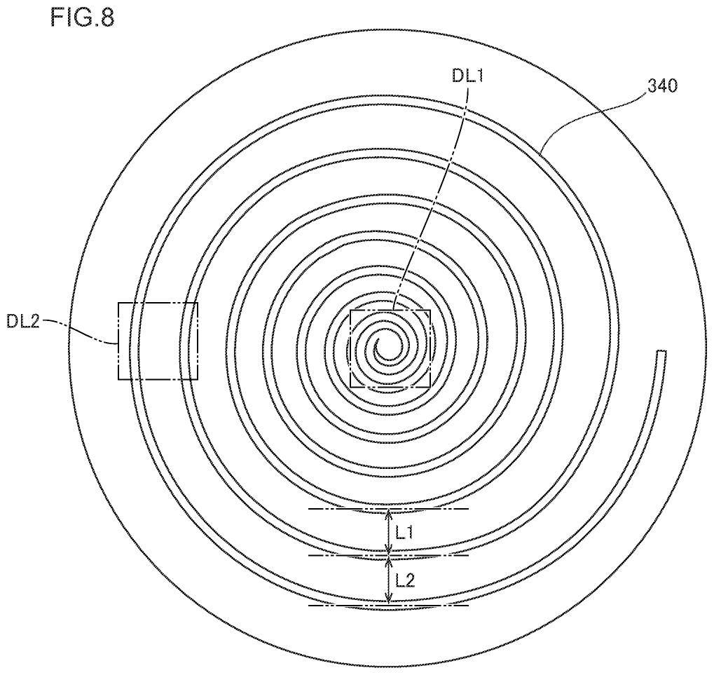

The present embodiment also differs from the first embodiment in the arrangement of the spaces 340 formed in the joining layer 300. In FIG. 8, a configuration of the joining layer 300 according to the present embodiment is schematically drawn using a similar method to FIG. 3. As shown in FIG. 8, only one space 340 is formed in the joining layer 300 in the present embodiment so as to spirally extend from the center of the joining layer 300. A width dimension of the space 340 is uniform along the entire space 340. Within the spirally-extending space 340, an interval between mutually adjacent portions in a radial direction gradually increases from the center toward the outer circumferential side of the joining layer 300. For example, a dimension L2 shown in FIG. 8 is larger than a dimension L1 on an inner side of the dimension L2.

As a result, the space proportion in the central part (for example, a region enclosed by the dotted line DL1) of the joining layer 300 becomes larger than the space proportion in the outer circumferential part (for example, a region enclosed by the dotted line DL2) of the joining layer 300. Even with such a configuration, a similar effect to that described in the first embodiment can be produced.

A fifth embodiment will be described. Hereinafter, differences from the first embodiment will be mainly described and descriptions of features in common with the first embodiment will be omitted when appropriate.

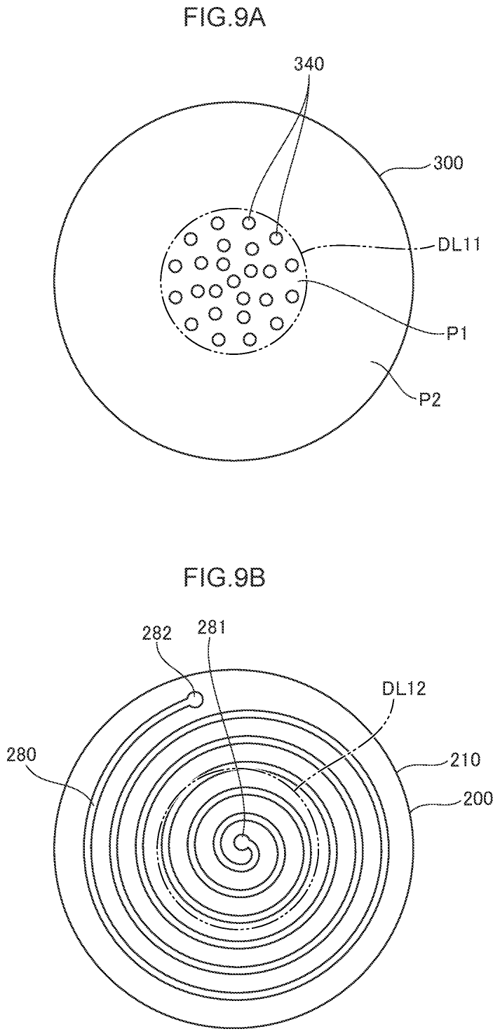

In FIG. 9A, a configuration of the joining layer 300 according to the present embodiment is schematically drawn using a similar method to FIG. 3. In the present embodiment, the spaces 340 are formed in plurality in the joining layer 300 and all of the spaces 340 are circular spaces in a top view in a similar manner to the first embodiment. In addition, the shapes of the respective spaces 340 are all the same. However, the spaces 340 according to the present embodiment are only arranged in the central part of the joining layer 300 or, more specifically, inside a region indicated by a dotted line DL11 and are not arranged outside of this region.

In FIG. 9B, a shape of the refrigerant flow path 280 formed in the base plate 200 according to the present embodiment is schematically drawn in a top view. While only a portion of the base plate 200 inside the surface 210 is drawn in FIG. 9B, alternatively, an aspect in which the refrigerant flow path 280 extends to a region outside of the surface 210 in a top view may be adopted. A dotted line DL12 in FIG. 9B represents a portion that overlaps with the dotted line DL11 in a top view.

As shown in FIG. 9B, the base plate 200 is provided with an inlet part 281 and an outlet part 282. The inlet part 281 is an inlet of a refrigerant which is supplied to the base plate 200 from outside and the outlet part 282 is an outlet of the refrigerant having passed through the refrigerant flow path 280. Both the inlet part 281 and the outlet part 282 are holes which are formed in the surface 220 of the base plate 200 and which are connected to a flow path FP.

The refrigerant flow path 280 according to the present embodiment is a single flow path which is formed so as to spirally extend. The inlet part 281 provided at one end of the refrigerant flow path 280 is provided at a center of the surface 210 in a top view or at a position in a vicinity thereof and is inside the region enclosed by the dotted line DL12. The outlet part 282 provided at the other end of the refrigerant flow path 280 is provided at a position in a vicinity of an outer circumferential end of the surface 210 in a top view and is outside the region enclosed by the dotted line DL12.

A portion of the joining layer 300 inside the dotted line DL11 in FIG. 9A will also be hereinafter referred to as a “first portion P1”. In addition, a portion of the joining layer 300 outside the dotted line DL11 will also be hereinafter referred to as a “second portion P2”. The spaces 340 described earlier are only arranged in the first portion P1 and not in the second portion P2.

The first portion P1 of the joining layer 300 is a portion which overlaps with the portion of the refrigerant flow path 280 inside the dotted line DL12 in a top view. In other words, the first portion P1 is a portion which overlaps with an upstream side of the refrigerant flow path 280 in a top view.

In addition, the second portion P2 of the joining layer 300 is a portion which overlaps with the portion of the refrigerant flow path 280 outside the dotted line DL12 in a top view. In other words, the second portion P2 is a portion which overlaps with a downstream side of the refrigerant flow path 280 in a top view.

By adopting the configuration described above, in the present embodiment, the space proportion in the first portion P1 of the joining layer 300 which overlaps with the upstream side of the refrigerant flow path 280 is made larger than the space proportion in the second portion P2 of the joining layer 300 which overlaps with the downstream side of the refrigerant flow path 280.

In semiconductor manufacturing equipment such as an etching device, cleaning inside the equipment may be successively performed after processing of the substrate W is completed. While the base plate 200 is supplied with a low-temperature refrigerant from the inlet part 281 during processing of the substrate W, once cleaning starts, the base plate 200 is supplied with a refrigerant at a higher temperature than before from the inlet part 281. Therefore, immediately after the start of cleaning, the temperature of the base plate 200 on the upstream side of the refrigerant flow path 280 rises first and the temperature of the base plate 200 on the downstream side of the refrigerant flow path 280 rises later. In this manner, a temporary temperature difference is created in the base plate 200 upon start of cleaning. Although a similar temperature difference is also created in the dielectric substrate 100 due to heat transfer from the base plate 200, since a ceramic sintered compact is often used as the dielectric substrate 100 as in the present embodiment, such a temperature difference is not preferable.

As a countermeasure, in the electrostatic chuck 10 according to the present embodiment, the space proportion in the first portion P1 of the joining layer 300 which overlaps with the upstream side of the refrigerant flow path 280 is made larger than the space proportion in the second portion P2 of the joining layer 300 which overlaps with the downstream side of the refrigerant flow path 280. While heat transfer from a portion of the base plate 200 that reaches a high temperature first (in other words, the portion inside the dotted line DL12) to the dielectric substrate 100 is suppressed by the first portion P1, heat transfer from a portion of the base plate 200 that reaches a high temperature later (in other words, the portion outside the dotted line DL12) to the dielectric substrate 100 is relatively promoted by the second portion P2. Accordingly, a temperature difference in the dielectric substrate 100 can be suppressed.

Note that when the inlet part 281 and the outlet part 282 have been interchanged or, in other words, when the refrigerant is supplied from the outer circumferential part and discharged from the central part of the base plate 200, for example, the spaces 340 may only be arranged outside of the dotted line DL11.

However, during the processing of the substrate W, a temperature of the central part of the substrate W tends to be lower than that of the outer circumferential part of the substrate W. Therefore, preferably, in addition to providing the inlet part 281 in the central part as in the present embodiment, the first portion P1 with a high space proportion is provided at a position closer to center than the second portion P2 with a low space proportion. Adopting such a configuration enables the temperature of the central part of the substrate W to be raised during processing and the in-plane temperature distribution of the substrate W to be made nearly uniform in a similar manner to the other embodiments.

The arrangement of the spaces 340 in the joining layer 300 may differ from the example shown in FIG. 9A. For example, the spaces 340 may be arranged as in the examples shown in any of FIGS. 3, 6, 7, and 8.

The present embodiment has been described above with reference to specific examples. However, it is to be understood that the present disclosure is not limited to the specific examples. Appropriate design modifications of the specific examples made by persons skilled in the art are also included in the scope of the present disclosure insofar as such modifications possess features of the present disclosure. The respective elements included in each specific example described above and arrangements, conditions, shapes, and the like of such elements are not limited to those exemplified and can be modified as appropriate. Combinations of the respective elements included in each specific example described above can be appropriately changed insofar as no technical contradictions arise from such changes.

What is claimed is:

1. An electrostatic chuck, comprising:
a dielectric substrate which includes a placement surface on which an attracted object is to be placed and in which through holes that penetrate the placement surface are formed;
an electrode terminal which is provided on a surface of the dielectric substrate on an opposite side to the placement surface;
a base plate to be joined to the surface of the dielectric substrate on the opposite side to the placement surface; and
a joining layer which is provided between the dielectric substrate and the base plate and which is formed of an insulating material, wherein
when viewed from a direction perpendicular to the placement surface,
at least one space is formed at a position within the joining layer that does not overlap with any of the through holes and the electrode terminal.

2. The electrostatic chuck according to claim 1, wherein
when viewed from a direction perpendicular to the placement surface,
when a proportion occupied by an area of the at least one space per unit area of the joining layer is assumed to be a space proportion,
the space proportion in a central part of the joining layer is larger than the space proportion in an outer circumferential part of the joining layer.

3. The electrostatic chuck according to claim 2, wherein
the at least one space comprises spaces formed in plurality, and
a density of the spaces in a central part of the joining layer is higher than a density of the spaces in an outer circumferential part of the joining layer.

4. The electrostatic chuck according to claim 2, wherein
the at least one space comprises spaces formed in plurality, and
each of the spaces arranged in a central part of the joining layer is larger than each of the spaces arranged in an outer circumferential part of the joining layer.

5. The electrostatic chuck according to claim 1, wherein
the at least one space is formed so as to penetrate the joining layer in a direction perpendicular to the placement surface.

6. The electrostatic chuck according to claim 1, wherein
an insulator film is provided on a surface of the base plate on the joining layer-side.

7. The electrostatic chuck according to claim 6, wherein
the insulator film is a film formed by spraying.

8. The electrostatic chuck according to claim 1, wherein
the joining layer is a layer created by curing a solid adhesive sheet on which a space part which is a depression or a through hole is formed in advance.

9. The electrostatic chuck according to claim 1, wherein
a refrigerant flow path for supplying a refrigerant is formed in the base plate, and
when viewed from a direction perpendicular to the placement surface,
when a proportion occupied by an area of the at least one space per unit area of the joining layer is assumed to be a space proportion,
the space proportion in a first portion of the joining layer which overlaps with an upstream side of the refrigerant flow path is larger than the space proportion in a second portion of the joining layer which overlaps with a downstream side of the refrigerant flow path.

10. The electrostatic chuck according to claim 9, wherein
when viewed from a direction perpendicular to the placement surface,
the first portion is at a position closer to center than the second portion.

11. A method of manufacturing an electrostatic chuck, comprising the steps of:
preparing a dielectric substrate which includes a placement surface on which an attracted object is to be placed, in which through holes that penetrate the placement surface are formed, and in which an electrode terminal is provided on a surface on an opposite side to the placement surface;
preparing a base plate;
preparing a solid adhesive sheet which is an insulating member and on which a space part being a depression or a through hole has been formed;
causing a surface of the dielectric substrate on the opposite side to the placement surface and the base plate to oppose each other and sandwiching the adhesive sheet between the dielectric substrate and the base plate so that the space part does not overlap with both the through holes and the electrode terminal; and
curing the adhesive sheet.
